(19) United States
(12) Patent Application Publication
(10) Pub. No.: US 2026/0245620 A1
(43) Pub. Date: Aug. 20, 2026

(54) MEMORY SYSTEM, MEMORY DEVICE AND OPERATING METHOD THEREOF

(71) Applicant: MACRONIX INTERNATIONAL CO., LTD., HSINCHU (TW)

(72) Inventors: Po-Hao TSENG, Taichung City (TW); Tian-Cih BO, Zhubei City (TW)

(21) Appl. No.: 19/302,145

(22) Filed: Aug. 18, 2025

Related U.S. Application Data
(60) Provisional application No. 63/761,133, filed on Feb. 20, 2025.

(51) Int. Cl. G11C 16/04

(52) U.S. Cl. CPC G11C 16/0483

(57) ABSTRACT

A memory device comprises a first memory string and a second memory string. The first memory string is configured to receive a first string select line signal to compare a first stored data bit and a first input bit. The second memory string is configured to receive a second string select line signal to compare the first stored data bit and the first input bit, wherein the first memory string comprises a first transistor, when the first input bit has a first logic value, the first string select line signal has a first voltage level, when the first input bit has a second logic value, the first string select line signal has a second voltage level, and the first voltage level is within a linear region of the first transistor.

### CROSS-REFERENCE TO RELATED APPLICATION

This application claims priority to U.S. Provisional Application No. 63/761,133, filed February, 20, 2025, which is herein incorporated by reference in its entirety.

### BACKGROUND

### Technical Field

The present disclosure relates to a memory technique. More particularly, the present disclosure relates to a memory system, a memory device and an operating method of a memory device.

### Description of Related Art

As the raising of big data and AI hardware accelerator, the data comparing/searching is essential functions for these two directions. Highly parallel searching can be implemented by the existing ternary content addressable memory (TCAM). Conventional TCAM is typically composed of SRAM thus suffer low memory density and high access power. To save power consumption with dense memory density, the nonvolatile based TCAM arrays were proposed recently.

### SUMMARY

The present disclosure provides a memory device. The memory device comprises a first memory string and a second memory string. The first memory string is configured to receive a first string select line signal to compare a first stored data bit and a first input bit. The second memory string is configured to receive a second string select line signal to compare the first stored data bit and the first input bit, wherein the first memory string comprises a first transistor, when the first input bit has a first logic value, the first string select line signal has a first voltage level, when the first input bit has a second logic value, the first string select line signal has a second voltage level, and the first voltage level is within a linear region of the first transistor.

In some embodiments, the second memory string comprises a second transistor, and a control terminal of the first transistor and a control terminal of the second transistor are configured to receive the first string select line signal and the second string select line signal, respectively.

In some embodiments, each of the control terminal of the first transistor and the control terminal of the second transistor is configured to receive a predetermined positive bias, to trim each of the first transistor and the second transistor.

In some embodiments, after each of the first transistor and the second transistor is trimmed, each of the first transistor and the second transistor has a trim threshold voltage level.

In some embodiments, when the first input bit has the first logic value, the second string select line signal has the second voltage level, and when the first input bit has the second logic value, the second string select line signal has the first voltage level.

In some embodiments, the first memory string and the second memory string comprise a third transistor and a fourth transistor, respectively, the third transistor and the fourth transistor are configured to store the first stored data bit, the third transistor and the fourth transistor are coupled in series with the first transistor and the second transistor, respectively, and each of a control terminal of the third transistor and a control terminal of the fourth transistor is configured to receive a word line signal.

In some embodiments, when the first stored data bit has the first logic value, the third transistor and the fourth transistor has a first threshold voltage level and a second threshold voltage level, respectively, and when the first stored data bit has the second logic value, the third transistor and the fourth transistor has the second threshold voltage level and the first threshold voltage level, respectively.

In some embodiments, the first memory string and the second memory string comprise a third transistor and a fourth transistor, respectively, the third transistor and the fourth transistor are coupled in series with the first transistor and the second transistor, respectively, and a control terminal of the third transistor and a control terminal of the fourth transistor are configured to receive the first string select line signal and the second string select line signal.

In some embodiments, each of the control terminal of the first transistor, the control terminal of the second transistor, the control terminal of the third transistor and the control terminal of the fourth transistor is configured to receive a predetermined positive bias, to trim each of the first transistor, the second transistor, the third transistor and the fourth transistor.

The present disclosure provides an operating method of a memory device. The operating method comprises: comparing a first stored bit and a first input bit by a first memory string and a second memory string; generating a first string current signal by the first memory string; generating a second string current signal by the second memory string; comparing the first string current signal and the second string current signal with a predetermined current level; and when at least one of a current level of the first string current signal and a current level of the second string current signal is larger than the predetermined current level, re-trimming the memory device.

In some embodiments, the first memory string and the second memory string comprise a first transistor and a second transistor, respectively, a control terminal of the first transistor and a control terminal of the second transistor are configured to receive a first string select line signal and a second string select line signal, respectively, when the first input bit has a first logic value, the first string select line signal has a first voltage level, when the first input bit has a second logic value, the first string select line signal has a second voltage level, and the first voltage level is within a linear region of the first transistor.

In some embodiments, when the first input bit has the first logic value, the second string select line signal has the second voltage level, and when the first input bit has the second logic value, the second string select line signal has the first voltage level.

In some embodiments, the first memory string and the second memory string comprise a third transistor and a fourth transistor, respectively, the third transistor and the fourth transistor are configured to store the first stored data bit, the third transistor and the fourth transistor are coupled in series with the first transistor and the second transistor, respectively, and each of a control terminal of the third transistor and a control terminal of the fourth transistor is configured to receive a word line signal.

In some embodiments, when the first input bit and the first stored data bit have the first logic value and the second logic value, respectively, the first string current signal and the second string current signal have a first current level and a second current level, respectively.

In some embodiments, when the first input bit and the first stored data bit have the second logic value and the first logic value, respectively, the first string current signal and the second string current signal have the second current level and the first current level, respectively.

In some embodiments, the predetermined current level is equal to the first current level multiplied by 1.1.

In some embodiments, re-trimming the memory device comprises: applying a predetermined positive bias to each of the first transistor and the second transistor.

The present disclosure provides a memory system. The memory system comprises: a plurality of memory strings configured to generate a plurality of bit line signals, the plurality of memory strings comprising: a first memory string and a second memory string configured to receive a first string select line signal and a second string select line signal, respectively, to compare a first stored data bit and a first input bit, wherein the first memory string comprises a first transistor, when the first input bit has a first logic value, the first string select line signal has a first voltage level, when the first input bit has a second logic value, the first string select line signal has a second voltage level, and the first voltage level is within a linear region of the first transistor.

In some embodiments, the plurality of memory strings further comprise: a third memory string and a fourth memory string configured to receive a third string select line signal and a fourth string select line signal, respectively, to compare a second stored data bit and a second input bit, wherein the first memory string, the second memory string, the third memory string and the fourth memory string are configured to generate a first string current signal, a second string current signal, a third string current signal and a fourth string current signal, respectively, and configured to sum the first string current signal, the second string current signal, the third string current signal and the fourth string current signal to generate a first bit line signal in the plurality of bit line signals.

In some embodiments, the plurality of memory strings further comprise: a fifth memory string and a sixth memory string configured to receive a fifth string select line signal and a sixth string select line signal, respectively, to compare a third stored data bit and the first input bit, wherein the fifth memory string and the sixth memory string are configured to generate a fifth string current signal and a sixth string current signal, respectively, and configured to sum the fifth string current signal, the sixth string current signal to generate a second bit line signal in the plurality of bit line signals.

It is to be understood that both the foregoing general description and the following detailed description are examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a portion of a memory device, illustrated according to some embodiments of present disclosure.

FIG. 1B is a schematic diagram of the input bit received by the memory device having different logic values, illustrated according to some embodiments of present disclosure.

FIG. 1C is a schematic diagram of a distributions of the threshold voltage level, illustrated according to some embodiments of present disclosure.

FIG. 1D is a schematic diagram of voltages of string select line signals and currents passing through corresponding transistors, illustrated according to some embodiments of present disclosure.

FIG. 2A is a schematic diagram of the stored data bits stored in the memory device having different logic values, illustrated according to some embodiments of present disclosure.

FIG. 2B is a schematic diagram of voltages of the word line signals and currents passing through the corresponding transistors, illustrated according to some embodiments of present disclosure.

FIG. 3A and FIG. 3B are schematic diagrams of the memory device performing the search operation, illustrated according to some embodiments of present disclosure.

FIG. 4A is a schematic diagram of a memory device receiving input bit of different logic value, illustrated according to some embodiments of present disclosure.

FIG. 4B is a schematic diagram of the memory device performing the search operation, illustrated according to some embodiments of present disclosure.

FIG. 5A is a schematic diagram of distributions of threshold voltage levels of transistors in the string select line layers, illustrated according to some embodiments of present disclosure.

FIG. 5B and FIG. 5C are flowchart diagrams of operating methods of the memory device, illustrated according to some embodiments of present disclosure.

FIG. 6A is a schematic diagram of a memory system illustrated according to some embodiments of present disclosure.

FIG. 6B is a schematic diagram of further details of the memory system, illustrated according to some embodiments of present disclosure.

FIG. 6C and FIG. 6D are schematic diagrams of further details of the memory device, illustrated according to some embodiments of present disclosure.

### DETAILED DESCRIPTION

In the present disclosure, when an element is referred to as “connected” or “coupled”, it may mean “electrically connected” or “electrically coupled”. “Connected” or “coupled” can also be used to indicate that two or more components operate or interact with each other. In addition, although the terms “first”, “second”, and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

The present disclosure provides “Partial on” string select line input method to execute reliable in memory search (IMS) function with low variation mismatching current by using the string select line clamping technology. String select line cells in 3D-NAND string are with special trim threshold voltage level distribution for NAND string's switches. String select line cells with tight threshold voltage level distribution can provide clamping current with low variation in subthreshold region (i.e. partial on region) for the input signal.

String select line layer-1 to string select line layer-m (m is positive integer) are programmed to identical trim threshold voltage level which reduced the local electric field between different string select line layers for robust retention. String select line layers can provide better retention than other data layers (i.e. the data layers receive word line signals). To further improve IMS reliability, string select line re-trimming process is performed to get high searching accuracy after the baking. In this approach, the stored data with retention loss don't need be updated. Only string select line re-trimming is needed to keep same accuracy as original one.

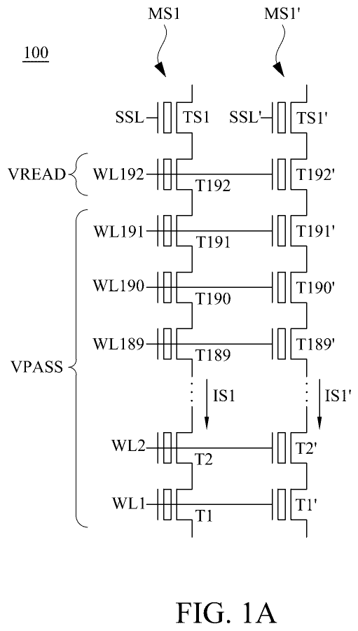

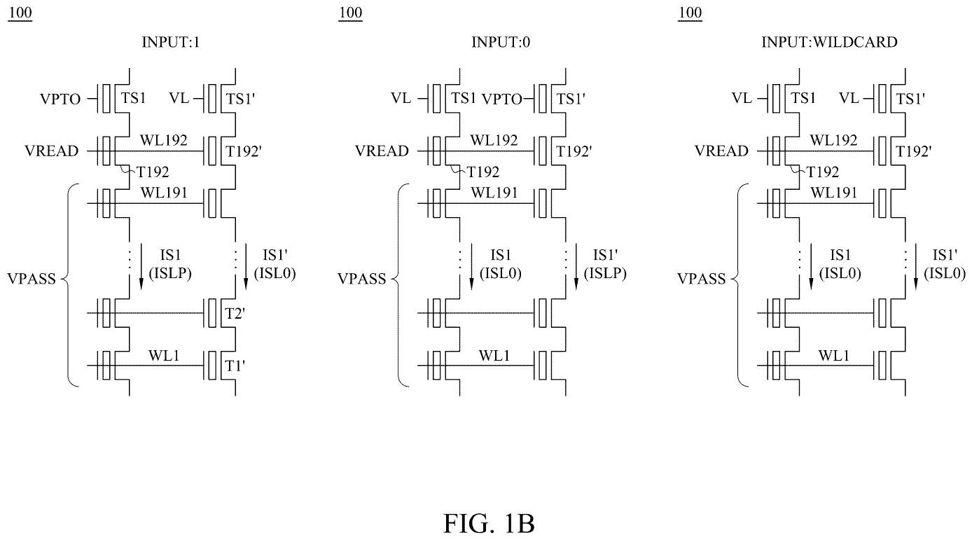

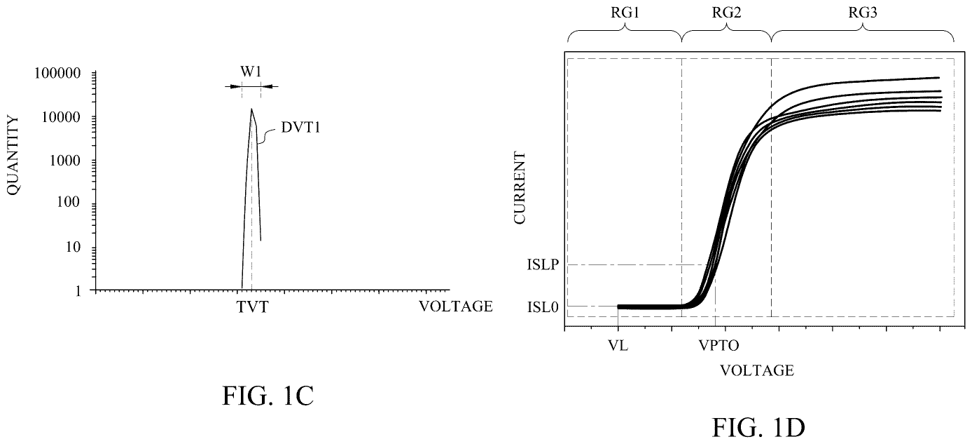

FIG. 1A is a schematic diagram of a portion of a memory device 100, illustrated according to some embodiments of present disclosure. In some embodiments, the memory device 100 can include multiple memory strings, such as memory strings MS1 and MS1′. In some embodiments, the memory strings MS1 and MS1′ are implemented by NAND strings.

As shown in FIG. 1A, the memory string MS1 includes transistors T1~T192 and TS1. The memory string MS1′ includes transistors T1′~T192′ and TS1′. However, the embodiments of present disclosure are not limited to this. In various embodiments, the memory string can include various quantities of transistors. Alternatively stated, 192 can be substituted by other positive integers.

In some embodiments, the transistors T1~T192 and TS1 are coupled in series with each other, and arranged in order. The transistors T1′~T192′ and TS1′ are coupled in series with each other, and arranged in order. Each of control terminals of the transistors T1 and T1′ is configured to receive the word line signal WL1. Each of control terminals of the transistors T2 and T2′ is configured to receive the word line signal WL2, and so on. Each of control terminals of the transistors T192 and T192′ is configured to receive the word line signal WL192. In summary, the transistors T1~T192 and T1′~T192′ are configured to receive the word line signals WL1~WL192.

On the other hand, a control terminal of the transistor TS1 is configured to receive a string select line signal SSL. A control terminal of the transistor TS1′ is configured to receive a string select line signal SSL′. Each of the transistors TS1 and TS1′ has a threshold voltage level TVT. Further details regarding the threshold voltage level TVT are described below with the embodiments associated with FIG. 1C.

In some embodiments, the string select line signals SSL SSL′ are configured to carry an input bit IDB1. The transistors T1 and T1′ are configured to store a stored data bit SDB1.

When performing a search operation to the stored data bit SDB1, the word line signal WL192 has a read voltage level VREAD, and each of the word line signals WL1~WL191 has a pass voltage level VPASS. Correspondingly, the memory device can compare the input bit IDB1 and the stored data bit SDB1, such that the memory strings MS1 and MS1′ generate string current signals IS1 and IS1′, respectively. At this moment, current levels of the string current signals IS1 and IS1′ correspond to the comparison result of the input bit IDB1 and the stored data bit SDB1. Correspondingly, the transistors TS1, TS1′, T192 and T192′ can be collectively referred to as an in flash search (IFS) cell.

FIG. 1B is a schematic diagram of the input bit IDB1 received by the memory device 100 having different logic values, illustrated according to some embodiments of present disclosure. Referring to FIG. 1A and FIG. 1B, for brevity, some labels of the memory device 100 are not shown in FIG. 1B.

In some embodiments, when a string select line signal has a voltage level VPTO, a corresponding transistor is turned partially on, such that a string current signal passing through the transistor can have a current level ISLP. When a string select line signal has a voltage level VL, a corresponding transistor is turned off, such that a string current signal passing through the transistor has a current level ISL0.

In some embodiments, the current level ISL0 is a zero current level. The voltage level VL is a zero voltage level. The current level ISLP is larger than the current level ISL0. The voltage level VPTO is larger than the voltage level VL. Further details regarding the voltage level VPTO and partially on are described below with the embodiments associated with FIG. 1D.

As shown in FIG. 1B, when the input bit IDB1 has a logic value 1, the string current signals SSL and SSL′ have the voltage levels VPTO and VL, respectively. Correspondingly, the transistor TS1 is turned partially on, and the transistor TS1′ is turned off.

When the input bit IDB1 has a logic value 0, the string current signals SSL and SSL′ have the voltage levels VL and VPTO, respectively. Correspondingly, the transistor TS1′ is turned partially on, and the transistor TS1 is turned off.

When the input bit IDB1 has a wildcard logic value, each of the string current signals SSL and SSL′ has the voltage level VL. Correspondingly, each of the transistors TS1′ and TS1 is turned off. In some embodiments, the wildcard logic value is indicated as an arbitrary logic value during input. Alternatively stated, the wildcard logic value can simultaneously represent the logic values 0 and 1 of the input bit IDB1.

FIG. 1C is a schematic diagram of a distributions of the threshold voltage level TVT, illustrated according to some embodiments of present disclosure. A horizontal axis shown in FIG. 1C corresponds to threshold voltage levels, and a vertical axis shown in FIG. 1C corresponds quantities of transistors.

Referring to FIG. 1A and FIG. 1C, the memory device 100 can include multiple transistors configured to receive string select line signals, such as transistors TS1 and TS1′. The threshold voltage levels of these transistors are located within the distribution of the threshold voltage level TVT. As shown in FIG. 1C, the distribution of the threshold voltage level TVT has a width W1.

In some embodiments, the width W1 is smaller than 0.6 volt. In some embodiments, the threshold voltage level TVT is equal to 1.5 volt. However, the embodiments of present disclosure are not limited to this.

In some embodiments, the memory device 100 trims the transistors, such that these transistors have the distribution of the threshold voltage level TVT. Specifically, when performing trimming, the memory device 100 can apply a predetermined positive bias to control terminals of the transistors, to inject charges into charge traps of the transistors, such that a width of distribution of the threshold voltage levels of the transistors is reduced from approximately 1 volt to the width W1. In some embodiments, the threshold voltage level TVT can be referred to as a trim threshold voltage level.

FIG. 1D is a schematic diagram of voltages of string select line signals and currents passing through corresponding transistors, illustrated according to some embodiments of present disclosure. A horizontal axis shown in FIG. 1D corresponds to voltage levels of string select line signals, and a vertical axis shown in FIG. 1D corresponds current levels of string current signals of passing through corresponding transistors.

Referring to FIG. 1A and FIG. 1D, the string select line signal SSL and the string current signal IS1 passing through the transistor TS1 described below as an example. However, the configurations described below are suitable for other string select line signals and other string current signals, such as the string select line signal SSL′ and the string current signal IS1′ passing through the transistor TS1′.

As shown in FIG. 1D, the voltage level of the string select line signal SSL can be separated into regions RG1~RG3. Voltage levels of the region RG1 is smaller than voltage levels of the region RG2, and voltage levels of the region RG2 is smaller than voltage levels of the region RG3. In some embodiments, the region RG1 is referred to as a cutoff region of the transistor TS1, the region RG2 is referred to as a linear region of the transistor TS1, and the region RG3 is referred to as a saturation region of the transistor TS1.

In some embodiments, the region RG1 is a region with voltage levels smaller than 1 volt. The region RG2 is a region with voltage levels between 1 volt and 3 volt. The region RG3 is a region with voltage levels larger than 3 volt.

When the voltage level of the string select line signal SSL is located in the region RG1, the string current signal IS1 has the current level ISL0, and the transistor TS1 is turned off. When the voltage level of the string select line signal SSL is located in the region RG2, the current level of the string current signal IS1 is increased with respect to increasing of the voltage level of the string select line signal SSL, and the transistor TS1 is referred to as turned partially on.

Referring to FIG. 1B and FIG. 1D, the voltage level VL is located within the region RG1, and the voltage level VPTO is located within the region RG2. In some embodiments, the voltage level VPTO can be equal to 1.5 volt, and the current level ISLP can between a current range of 1~10 nano-ampere. When the voltage level of the string select line signal SSL is located in the region RG3, the transistor TS1 can be referred to as turned fully on, and the current level of the string current signal IS1 is larger than the current level ISLP, such as 10~200 nano-ampere. In some embodiments, a value of the voltage level VPTO can be equal to a value of the threshold voltage level TVT.

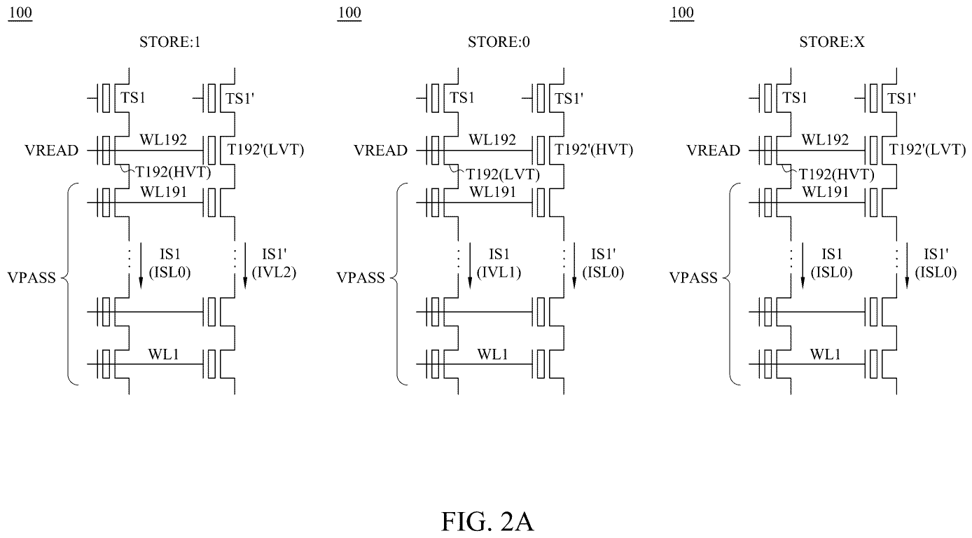

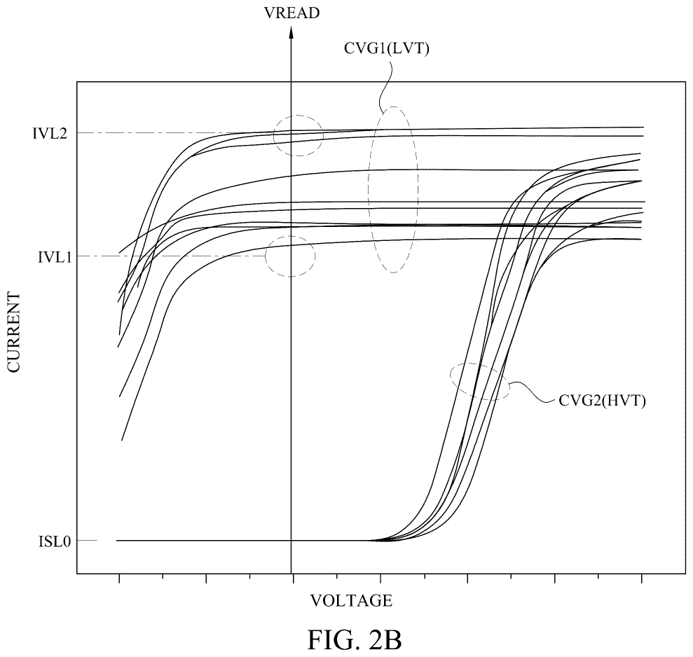

FIG. 2A is a schematic diagram of the stored data bits SDB1 stored in the memory device 100 having different logic values, illustrated according to some embodiments of present disclosure. Referring to FIG. 1A and FIG. 2A, for brevity, some labels of the memory device are not shown in FIG. 2A.

In some embodiments, the memory device 100 is configured to store one stored data bit by two transistors receiving the same word line signal. For example, the transistors T192 and T192′ are configured to store the stored data bit SDB1.

When the stored data bit SDB1 has the logic value 1, the transistors T192 and T192′ have threshold voltage levels HVT and LVT. At this moment, in response to the word line signal WL192 having the read voltage level VREAD, the transistor T192 is turned off and the transistor T192′ is turned on. In which the read voltage level VREAD is smaller than the threshold voltage level HVT and is larger than the threshold voltage level LVT.

When the stored data bit SDB1 has the logic value 0, the transistors T192 and T192′ have the threshold voltage levels LVT and HVT. At this moment, in response to the word line signal WL192 having the read voltage level VREAD, the transistor T192′ is turned off and the transistor T192 is turned on.

When the stored data bit SDB1 has a “don't care” logic value X, each of the transistors T192 and T192′ has the threshold voltage level HVT. At this moment, in response to the word line signal WL192 having the read voltage level VREAD, each of the transistors T192′ and T192 is turned off. In some embodiments, the “don't care” logic value X is indicated as an arbitrary logic value during storage. Alternatively stated, the “don't care” logic value X can simultaneously represent the logic values 0 and 1 of the stored data bit SDB1.

FIG. 2B is a schematic diagram of voltages of the word line signals and currents passing through the corresponding transistors, illustrated according to some embodiments of present disclosure. A horizontal axis shown in FIG. 2B corresponds to voltage levels of word line signals, and a vertical axis shown in FIG. 1D corresponds current levels of string current signals of passing through corresponding transistors receiving the word line signals.

As shown in FIG. 2B, the transistors having the threshold voltage level LVT correspond to the curve group CVG1, and the transistors having the threshold voltage level HVT correspond to the curve group CVG2. When the transistors have the threshold voltage level HVT, in response to the corresponding word line signals having the read voltage level VREAD, the string current signals of passing through corresponding transistors have the current level ISL0. When the transistors have the threshold voltage level LVT, in response to the corresponding word line signals having the read voltage level VREAD, the current levels of the string current signals of passing through corresponding transistors have a larger distribution range. Alternatively stated, the turned on currents of the transistors have a larger variation.

For example, referring to FIG. 2A and FIG. 2B, in a condition that each of the transistors TS1 and TS1′ is turned on, when the stored data bit SDB1 has the logic value 1, the string current signals IS1 and IS1′ have the current level ISL0 and IVL2, respectively. When the stored data bit SDB1 has the logic value 0, the string current signals IS1 and IS1′ have the current level IVL1 and ISL0, respectively. When the stored data bit SDB1 has the “don't care” logic value X, each of the string current signals IS1 and IS1′ has the current levels ISL0. In which the current level IVL1 is larger than the current level ISL0, and is smaller than the current level IVL2.

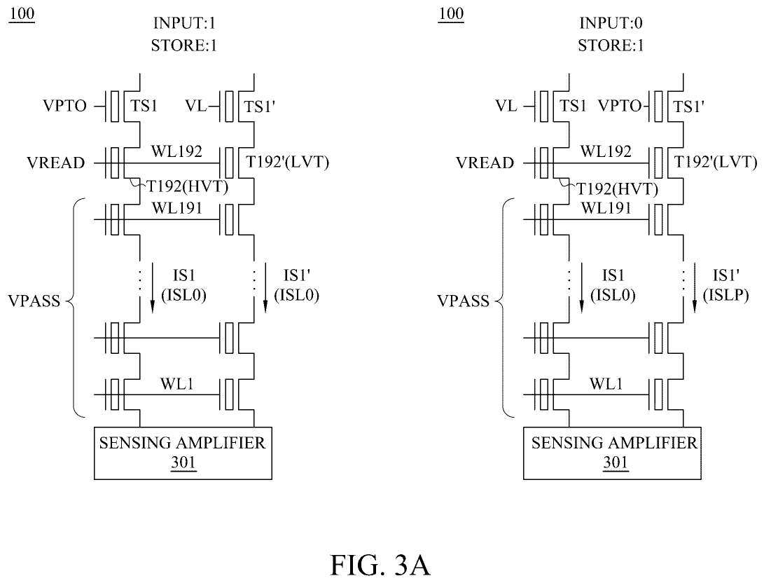

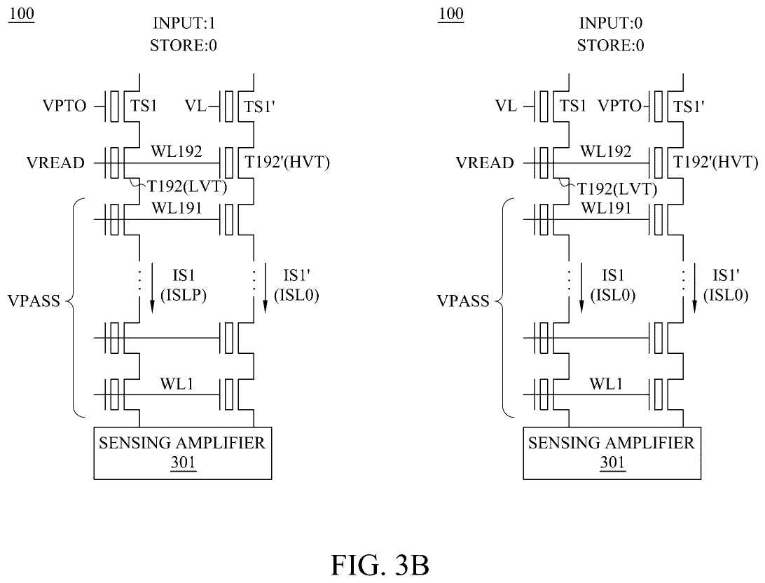

In order to reduce the variation of the currents, the memory device 100 turns each of the transistors TS1 and TS1′ partially on, to clamp the string current signals IS1 and IS1′. As a result, when the transistors are turned on, the current levels of the string current signals IS1 and IS1′ can be unified to the current level ISLP, in which the variation of the current level ISLP is lower. Further details regarding clamping the string current signals IS1 and IS1′ are described below with the embodiments associated with FIG. 3A and FIG. 3B.

FIG. 3A is a schematic diagram of the memory device 100 performing the search operation, illustrated according to some embodiments of present disclosure. As shown in FIG. 3A, the memory device 100 can further includes a sensing amplifier 301. The sensing amplifier 301 is configured to receive the string current signals generated by the memory strings, such as the string current signals IS1 and IS1′.

In the embodiment shown in FIG. 3A, the word line signal WL192 has the read voltage level VREAD, and each of the word line signals WL1~WL191 has the pass voltage level VPASS.

When the input bit IDB1 has the logic value 1 and the stored data bit SDB1 has the logic value 1, the string select line signal SSL′ has the voltage level VL and the transistor T192 has the threshold voltage level HVT, such that each of the transistors TS1′ and T192 is turned off. Correspondingly, each of the string current signals IS1 and IS1′ has the current level ISL0.

When the input bit IDB1 has the logic value 0 and the stored data bit SDB1 has the logic value 1, the transistor T192 has the threshold voltage level HVT and is turned off, such that string current signal IS1 has the current level ISL0. The transistor T192′ has the threshold voltage level LVT and is turned on. The string select line signal SSL′ has the voltage level VPTO, such that the transistor TS1′ is turned partially on. At this moment, the transistor TS1′ clamps the string current signal IS1′, such that the string current signal IS1′ has the current level ISLP.

FIG. 3B is a schematic diagram of the memory device 100 performing the search operation, illustrated according to some embodiments of present disclosure. In the embodiment shown in FIG. 3B, the word line signal WL192 has the read voltage level VREAD, and each of the word line signals WL1~WL191 has the pass voltage level VPASS.

When the input bit IDB1 has the logic value 1 and the stored data bit SDB1 has the logic value 0, the transistor T192′ has the threshold voltage level HVT and is turned off, such that string current signal IS1′ has the current level ISL0. The transistor T192 has the threshold voltage level LVT and is turned on. The string select line signals SSL has the voltage level VPTO, such that the transistor TS1 is turned partially on. At this moment, the transistor TS1 clamps the string current signal IS1, such that the string current signal IS1 has the current level ISLP.

When the input bit IDB1 has the logic value 0 and the stored data bit SDB1 has the logic value 0, the string select line signals SSL has the voltage level VL and the transistor T192′ has the threshold voltage level HVT, such that each of the transistors TS1 and T192′ is turned off. Correspondingly, each of the string current signals IS1 and IS1′ has the current level ISL0.

In summary, when the logic values of the input bit IDB1 and the stored data bit SDB1 are the same, the input bit IDB1 and the stored data bit SDB1 are match with each other. Correspondingly, the sensing amplifier 301 detects the current level ISL0 from the memory strings MS1 and MS1′.

In contrast, when the logic values of the input bit IDB1 and the stored data bit SDB1 are different, the input bit IDB1 and the stored data bit SDB1 are mismatch with each other. Correspondingly, the sensing amplifier 301 detects the current level ISLP from the memory strings MS1 and MS1′, that is the current level of low variation.

In some embodiments, the memory device 100 can also compare the input bit IDB1 with the stored data bits stored by the transistors T1~T191 and T1′~T191′.

Specifically, when comparing the input bit IDB1 with the stored data bit stored by the transistors T191 and T191′, the word line signal WL191 has the read voltage level VREAD, and each of the word line signals WL1~WL190 and WL192 has the pass voltage level VPASS. When comparing the input bit IDB1 with the stored data bit stored by the transistors T190 and T190′, the word line signal WL190 has the read voltage level VREAD, and each of the word line signals WL1~WL189 and WL191~WL192 has the pass voltage level VPASS, and so on. When comparing the input bit IDB1 with the stored data bit stored by the transistors T1 and T1′, the word line signal WL1 has the read voltage level VREAD, and each of the word line signals WL2~WL192 has the pass voltage level VPASS.

In some approaches, a memory device performing the search operation, the string current signals generated by the memory device has a larger variation, such that the sensing result of the sensing amplifier is not accurate.

Compared to above approaches, in the embodiments of present disclosure, the memory device 100 adjusts the string select line signals SSL and SSL′ to the voltage level VPTO of the linear region, such that the transistors TS1 and TS1′ are turned partially on, to clamp the string current signals IS1 and IS1′ has the current level ISLP with lower variation. As a result, an accuracy of the sensing result of the sensing amplifier 301 is higher.

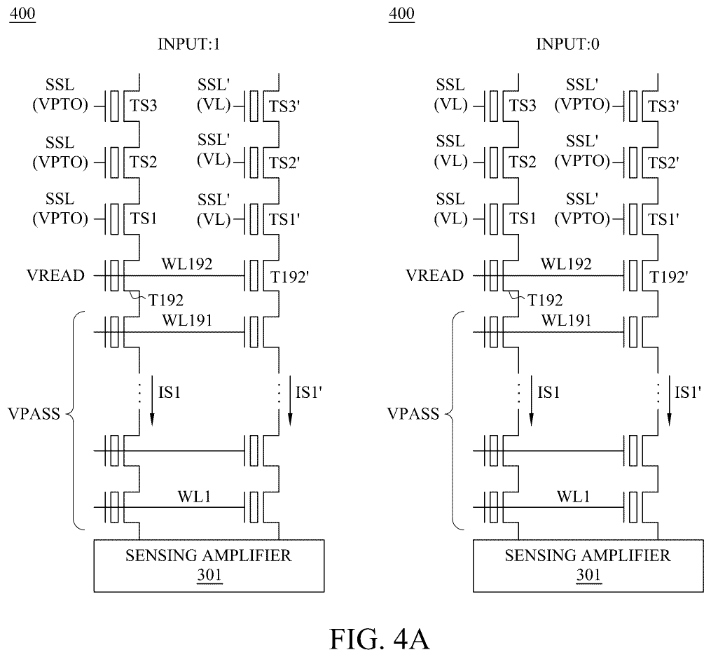

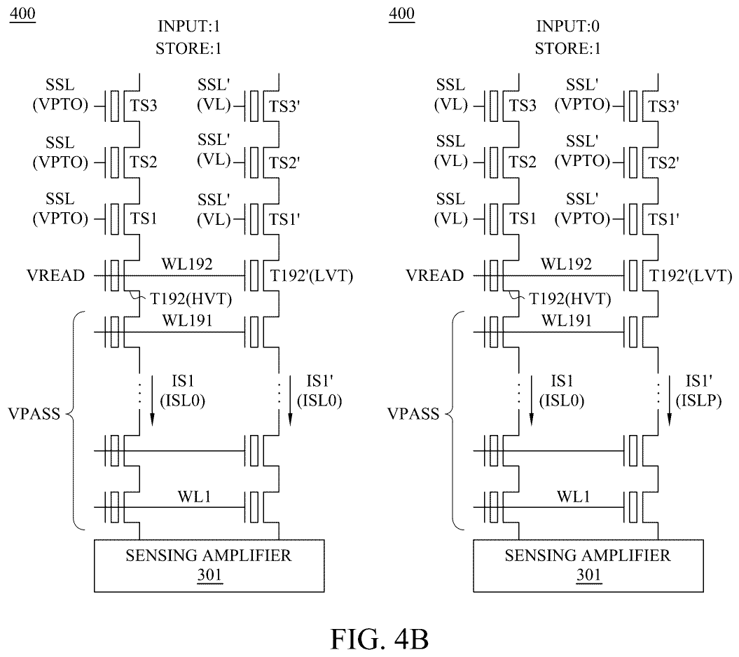

FIG. 4A is a schematic diagram of a memory device 400 receiving input bit of different logic value, illustrated according to some embodiments of present disclosure. Referring to FIG. 4A and FIG. 1A, the memory device 400 is an alternative embodiment of the memory device 100. Therefore, for brevity, some descriptions are not repeated.

Compared to the memory device 100, the memory device 400 transistors TS2, TS3, TS2′ and TS3′. The transistors TS1~TS3 are coupled in series with each other and arranged in order. The transistors TS1′~TS3′ are coupled in series with each other and arranged in order. The transistor TS1 is coupled between the transistors TS2 and T192. The transistor TS1′ is coupled between the transistors TS2′ and T192′.

In some embodiments, each of control terminals of the transistors TS1~TS3 is configured to receive the string select line signal SSL. Each of control terminals of the transistors TS1′~TS3′ is configured to receive the string select line signal SSL′. Alternatively stated, the string select line signals received by three string select line layers corresponding to the transistors TS1~TS3 and TS1′~TS3′ are the same, and operate simultaneously.

In some embodiments, each of the transistors TS1~TS3 and TS1′~TS3′ has the threshold voltage level TVT. During the search operation, the transistors TS1~TS3, TS1′~TS3′, T192 and T192′ can be referred to as one IFS cell.

When the input bit SDB1 has the logic value 1, the string select line signals SSL and SSL′ have the voltage level VPTO and VL, respectively, such that each of the transistors TS1~TS3 is turned partially on, and each of the transistors TS1′~TS3′ is turned off.

When the input bit SDB1 has the logic value 0, the string select line signals SSL and SSL′ have the voltage level VL and VPTO, respectively, such that each of the transistors TS1′~TS3′ is turned partially on, and each of the transistors TS1~TS3 is turned off.

In the embodiment shown in FIG. 4A, the memory device 400 includes three string select line layers, that is the transistors TS1~TS3 and TS1′~TS3′. However, the embodiments of present disclosure are not limited to this. In various embodiments, the memory device 400 can include various quantities of string select line layers, such as three to five layers.

In some embodiments, multiple string select line layers are programmed to identical trim threshold voltage level TVT, to reduce local electric field between different string select line layers, such that robust retention of the memory device 400 is better. Compared to data layers (such as transistors T1~T192 and T1′~T192′), the string select line layers can provide better retention. In some embodiments, the string select line layers are for query input, and the data layers are for storing database. The memory array of the memory device 400 can have one or more data layers.

In some approaches, when a memory device performing a search operation, threshold voltage levels in data layers affect local electric field in string select line layers, such that the retention is reduced.

Compared to above approaches, in the embodiments of present disclosure, the memory device 400 uses multiple string select line layers to reduce the effect of the local electric field, such that the retention is improved.

FIG. 4B is a schematic diagram of the memory device 400 performing the search operation, illustrated according to some embodiments of present disclosure. In the embodiment shown in FIG. 4B, the word line signal WL192 has the read voltage level VREAD, and each of the word line signals WL1~WL191 has the pass voltage level VPASS.

When the input bit IDB1 has the logic value 1 and the stored data bit SDB1 has the logic value 1, the string select line signal SSL′ has the voltage level VL and the transistor T192 has the threshold voltage level HVT, such that each of the transistors TS1′~TS3′ and T192 is turned off. Correspondingly, each of the string current signals IS1 and IS1′ has the current level ISL0.

When the input bit IDB1 has the logic value 0 and the stored data bit SDB1 has the logic value 1, the transistor T192 has the threshold voltage level HVT and is turned off, such that string current signal IS1 has the current level ISL0. The transistor T192′ has the threshold voltage level LVT and is turned on. The string select line signal SSL′ has the voltage level VPTO, such that each of the transistors TS1′~TS3′ is turned partially on. At this moment, each of the transistors TS1′~TS3′ clamps the string current signal IS1′, such that the string current signal IS1′ has the current level ISLP.

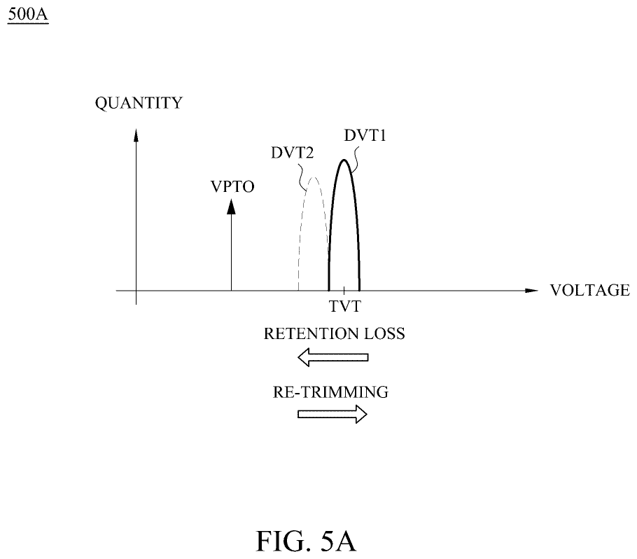

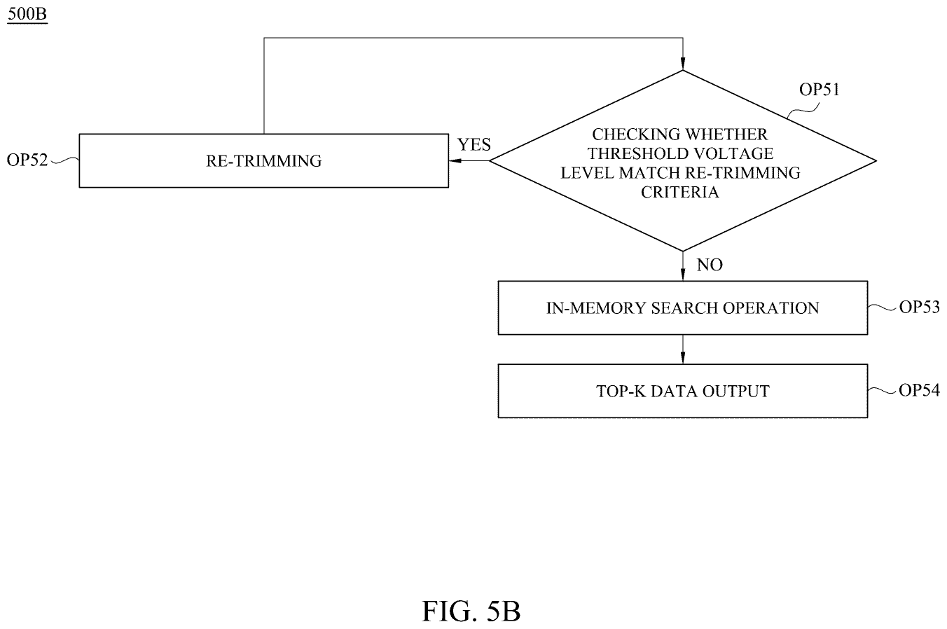

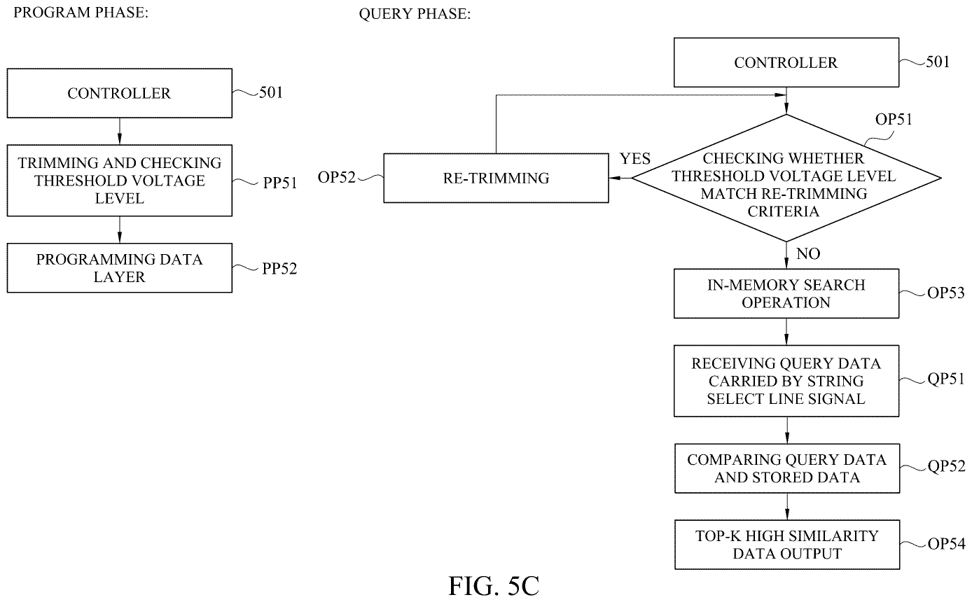

FIG. 5A is a schematic diagram 500A of distributions of threshold voltage levels of transistors in the string select line layers, illustrated according to some embodiments of present disclosure. A horizontal axis of the schematic diagram 500A corresponds to voltages, and a vertical axis of the schematic diagram 500A corresponds to quantities of transistors.

As shown in FIG. 5A, the schematic diagram 500A includes distributions DVT1 and DVT2. A voltage difference between the distribution DVT1 and the voltage level VPTO is larger than a voltage difference between the distribution DVT2 and the voltage level VPTO. The distributions DVT1 and DVT2 can correspond to the distributions of threshold voltage levels of transistors in the string select line layers. Referring to FIG. 1A, FIG. 4A and FIG. 5A, the transistors TS1~TS3 and TS1′~TS3′ are embodiments of the transistors in the string select line layers.

In some embodiments, when the trimming to the transistors in the string select line layers is complete, the transistors in the string select line layers correspond to the distribution DVT1. After being used for a period of time and/or exposed to high-temperature environments, the transistors in the string select line layers have retention loss, such that the transistors in the string select line layers correspond to the distribution DVT2.

For example, when the trimming is complete, each of the transistors TS1~TS3 and TS1′~TS3′ has the threshold voltage level TVT, and corresponds to the distribution DVT1. After being used for a period of time and/or exposed to high-temperature environments, due to retention loss, the threshold voltage levels of the transistors TS1~TS3 and TS1′~TS3′ are reduced, such that the transistors TS1~TS3 and TS1′~TS3′ correspond to the distribution DVT2.

When the transistors TS1~TS3 and TS1′~TS3′ correspond to the distribution DVT1, the transistors TS1~TS3 and TS1′~TS3′ can clamp the string current signals IS1 and IS1′ to the current level ISLP. When the transistors TS1~TS3 and TS1′~TS3′ correspond to the distribution DVT2, the transistors TS1~TS3 and TS1′~TS3′ can clamp the string current signals IS1 and IS1′ to a current level ISLP′. In which the current level ISLP′ is larger than the current level ISLP.

Correspondingly, the memory device 400 can determine whether performing re-trimming to the transistors TS1~TS3 and TS1′~TS3′ according to the string current signals IS1 and IS1′. During the re-trimming, the memory device 400 can apply the predetermined positive bias to the control terminals of the transistors TS1~TS3 and TS1′~TS3′, to inject charges into the charge traps of the transistors TS1~TS3 and TS1′~TS3′, the distribution of the transistors TS1~TS3 and TS1′~TS3′ is back to the distribution DVT2 from the distribution DVT1.

After the re-trimming, the transistors TS1~TS3 and TS1′~TS3′ can clamp the string current signals IS1 and IS1′ to the current level ISLP. Further details regarding re-trimming is described below with the embodiment associated with FIG. 5B.

FIG. 5B is a flowchart diagram of an operating method 500B of the memory device, illustrated according to some embodiments of present disclosure. As shown in FIG. 5B, the operating method 500B includes operations OP51~OP54. Referring to FIG. 1A to FIG. 5B, the operating method 500B can be performed to the memory device 100 or the memory device 400. The example described below is the memory device 400 performing the operating method 500B.

During the operation OP51, the memory device 400 checks whether the threshold voltages of the string select line layers match the criteria of re-trimming. Specifically, the memory device 400 detects the string current signals IS1 and IS1′ by the sensing amplifier 301, and compares the current levels of the string current signals IS1 and IS1′ with the current level ISLP. When differences between the current levels of the string current signals IS1 and IS1′ and the current level ISLP is too large, the memory device 400 is required to be re-trimming.

For example, when at least one of the current levels of the string current signals IS1 and IS1′ is larger than a predetermined current level, the memory device 400 determines that the threshold voltage levels of the transistors TS1~TS3 and TS1′~TS3′ match the criteria of re-trimming, and the operation OP52 is performed. When each of the current levels of the string current signals IS1 and IS1′ is smaller than the predetermined current level, the memory device 400 determines that the threshold voltage levels of the transistors TS1~TS3 and TS1′~TS3′ does not match the criteria of re-trimming, and the operation OP53 is performed.

In some embodiments, the predetermined current level is equal to the current level ISLP multiplied by 1.1. However, the embodiments of present disclosure are not limited to this. In various embodiments, the memory device 400 can include various criteria of re-trimming. Alternatively stated, 1.1 can be substituted by other ratio.

During the operation OP52, the memory device 400 re-trims the threshold voltage levels of the string select line layers. Specifically, the memory device 400 applies the predetermined positive bias to the control terminals of the transistors TS1~TS3 and TS1′~TS3′, to inject charges into the charge traps of the transistors TS1~TS3 and TS1′~TS3′, the distribution of the transistors TS1~TS3 and TS1′~TS3′ is back to the distribution DVT2 from the distribution DVT1.

During the operation OP53, the memory device 400 performs the in-memory search operation, such as the operation shown in FIG. 4B. After the operation OP53, the memory device 400 performs the operation OP54.

During the operation OP54, the memory device 400 outputs Top-K data. For example, the memory device 400 outputs K data instances with highest similarities. In which K is a positive integer.

In summary, since the string select line layers can clamp the string current signals, after retention loss, the memory device does not need re-programming the data layers. As a result, time and cost of re-programming are saved.

FIG. 5C is a flowchart diagram of an operating method 500C of the memory device, illustrated according to some embodiments of present disclosure. As shown in FIG. 5C, the operating method 500C can be performed by a controller 501 operating the memory device 100 or the memory device 400. In some embodiments, the controller 501 can be included in the memory device 100 or the memory device 400. The example described below is the memory device 400 performing the operating method 500C.

As shown in FIG. 5C, the operating method 500C includes a program phase and a query phase. In some embodiments, the query phase is performed after the program phase. The program phase includes operations PP51 and PP52. The query phase includes operations OP51~OP54, QP51 and QP52.

During the operation PP51, the controller 501 controls the memory device 400 to perform initializing. Specifically, the memory device 400 trims the transistors TS1~TS3 and TS1′~TS3′ in the string select line layers, and checks the threshold voltage level TVT of the transistors TS1~TS3 and TS1′~TS3′. In some embodiments, during the operation PP51, the controller 501 can store the threshold voltage level TVT, to perform following comparisons.

Referring to FIG. 5C and FIG. 5B, in some embodiments, a voltage level of the predetermined positive bias applied to the transistors TS1~TS3 and TS1′~TS3′ during the operation PP51 is equal to a voltage level of the predetermined positive bias applied to the transistors TS1~TS3 and TS1′~TS3′ during the operation OP52. Alternatively stated, waveforms of the predetermined positive bias of the trimming operation and the re-trimming operation are the same.

During the operation PP52, the controller 501 controls the memory device 400 to program the data layers. Specifically, the memory device 400 writes the stored data bits into the transistors T1~T192 and T1′~T192′ corresponding to the word line signals WL1~WL192. After the operation PP52, the memory device 400 can perform the query phase.

During the query phase, the controller 501 controls the memory device 400 to perform the operations OP51~OP54. Referring to FIG. 5C and FIG. 5B, details of the operations OP51~OP54 are described above in the embodiments shown in FIG. 5B. Therefore, for brevity, some descriptions of the operations OP51~OP54 are not repeated.

As shown in FIG. 5C, between the operations OP53 and OP54, the memory device 400 can further perform the operations QP51 and QP52.

During the operation QP51, the memory device 400 receives query data carried by the string select line signals. Referring to FIG. 4B and FIG. 5C, the query data can include the input bit IDB1 carried by the string select line signals SSL and SSL′.

During the operation QP52, the memory device 400 compares the query data and stored data corresponding to the word line signals WL1~WL192. Referring to FIG. 4B and FIG. 5C, the stored data can include the stored data bit SDB1.

During the operation OP54, the memory device 400 outputs K data instances with highest similarities (that is, Top-K data instances).

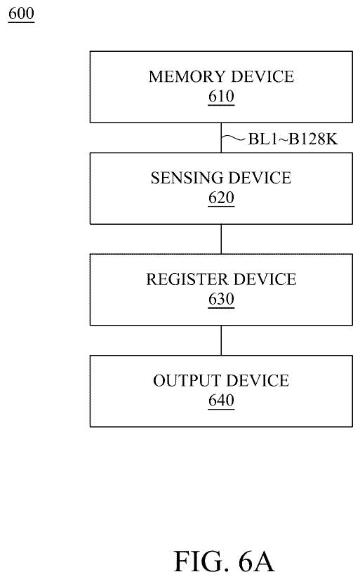

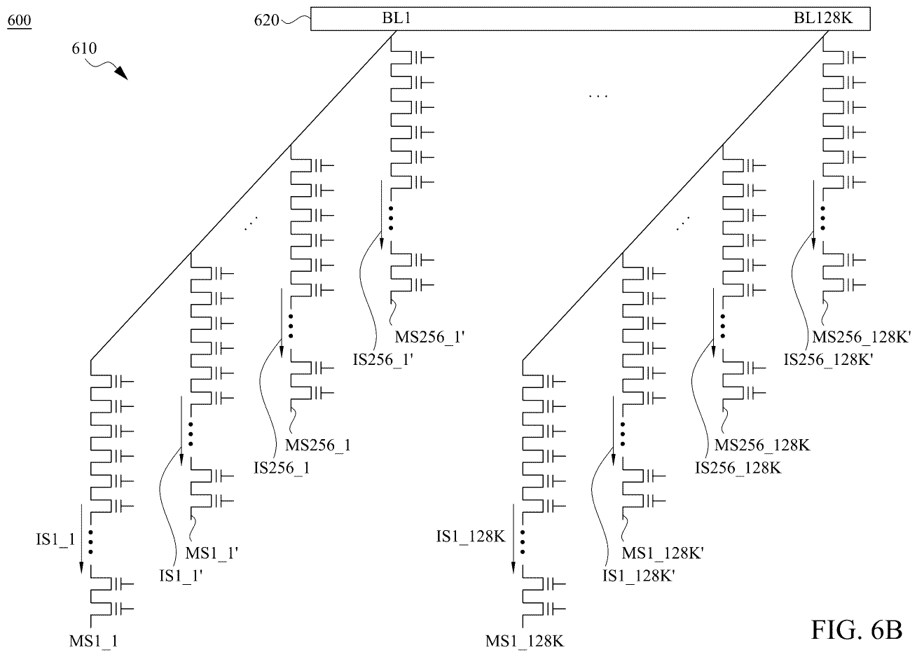

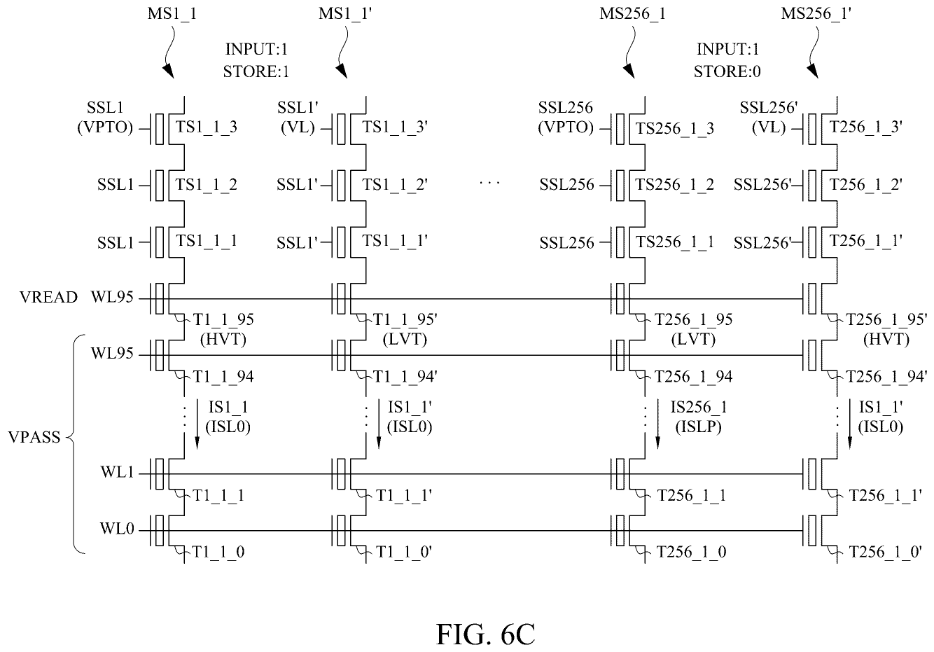

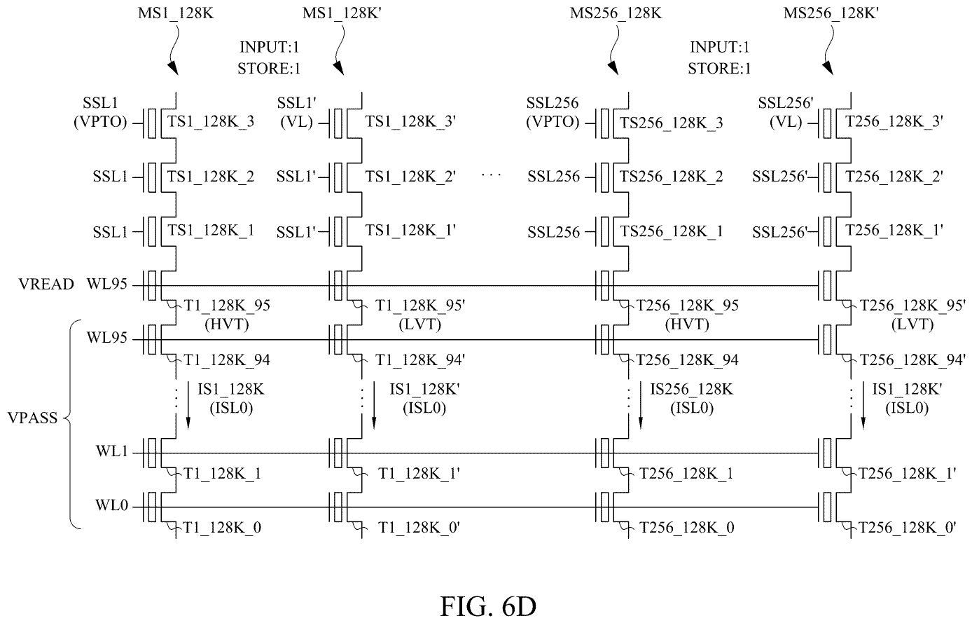

FIG. 6A is a schematic diagram of a memory system 600 illustrated according to some embodiments of present disclosure. As shown in FIG. 6A, the memory system 600 includes a memory device 610, a sensing device 620, a register encoding device 630 and an output device 640.

In some embodiments, the memory device 610 is configured to generate bit line signals BL1-BL128K, in which K in 128K represents one thousand. However, the present disclosure is not limited to this. In various embodiments, the memory device 610 can generate various quantities of bit line signals, that is, 128K can be substituted by other positive integers. The sensing device 620 can include a page buffer and a sensing amplifier, and configured to sense corresponding searching results of the bit line signals BL1-BL128K. The register encoding device 630 can includes cache registers and priority encoders. The output device 640 is configured to output the matching results of the memory device 610.

In some embodiments, the process performed by the register encoding device 630 to the bit line signals includes logic processes of AND logic, OR logic or counting, and also may include combining processes of the three logic processes described above. Referring to FIG. 1A to FIG. 6A, the register encoding device 630 can receive sense results from the memory device 100, 400 and/or 610, and controls sequencing (whether serial or parallel) and combines sense results to produce overall search results as the matching results outputted from the output device 640.

In some embodiments, the register encoding device 630 is further configured to perform priority encoding to the corresponding searching results of the bit line signals BL1-BL128K. For example, the register encoding device 630 collectively processes the corresponding searching results of the bit line signals BL1-BL128K, and preferentially select an address of a bit line signal corresponding to the best searching result (that is, the value of the input data and the value of the stored data are closest to each other).

FIG. 6B is a schematic diagram of further details of the memory system 600, illustrated according to some embodiments of present disclosure. In some embodiments, the memory device 610 can be implemented by 3D memory architecture. As shown in FIG. 6B, memory device 610 includes memory strings MS1_1~MS1_128K, MS1_1′~MS1_128K′, MS2_1~MS2_128K, MS2_1′~MS2_128K′, ..., MS256_1~MS256_128K and MS256_1′~MS256_128K′.

In some embodiments, the memory strings MS1_1~MS256_1 and MS1_1′~MS256_1′ are configured to generate string current signals IS1_1~IS256_1 and IS1_1′~IS256_1′, respectively, and configured to sum the string current signals IS1_1~IS256_1 and IS1_1′~IS256_1′ to generate the bit line signal BL1. Alternatively stated, a current level of the bit line signal BL1 is equal to a summation of the current levels of the string current signals IS1_1~IS256_1 and IS1_1′~IS256_1′.

Similarly, the memory strings MS1_128K~MS256_128K and MS1_128K′~MS256_128K′ are configured to generate string current signals IS1_128K~IS256_128K and IS1_128K′~IS256_128K′, respectively, and configured to sum the string current signals IS1_128K~IS256_128K and IS1_128K′~IS256_128K′ to generate the bit line signal BL128K. Alternatively stated, a current level of the bit line signal BL128K is equal to a summation of the current levels of the string current signals IS1_128K~IS256_128K and IS1_128K′~IS256_128K′.

Referring to FIG. 4A, FIG. 4B and FIG. 6B, configurations of the memory strings MS1_1~MS1_128K, MS1_1′~MS1_128K′, MS2_1~MS2_128K, MS2_1′~MS2_128K′, . . . , MS256_1~MS256_128K and MS256_1′~MS256_128K′ are similar with the configuration of the memory strings MS1 and MS1′. Configurations of the string current signals IS1_1~IS256_1, IS1_1′~IS256_1′, IS1_128K~IS256_128K and IS1_128K′~IS256_128K′ are similar with the configuration of the string current signals IS1 and IS1′. Therefore, for brevity, some descriptions are not repeated.

For example, the memory strings MS1_1 and MS1_1′ can be implemented by the memory strings MS1 and MS1′. The string current signals IS1_1 and IS1_1′ correspond to the string current signals IS1 and IS1′, respectively.

FIG. 6C is a schematic diagram of further details of the memory device 610, illustrated according to some embodiments of present disclosure. As shown in FIG. 6C, the memory string MS1_1 includes transistors T1_1_0~T1_1_95 and TS1_1_1~TS1_1_3. The memory string MS1_1′ includes transistors T1_1_0′~T1_1_95′ and TS1_1_1′~TS1_1_3′. The memory string MS256_1 includes transistors T256_1_0~T256_1_95 and TS256_1_1~TS256_1_3. The memory string MS256_1′ includes transistors T256_1_0′~T256_1_95′ and TS256_1_1′~TS256_1_3′.

The transistors T1_1_0~T1_1_95 and TS1_1_1~TS1_1_3 are coupled in series with each other and arranged in order. The transistors T1_1_0′~T1_1_95′ and TS1_1_1′~TS1_1_3′ are coupled in series with each other and arranged in order. The transistors T256_1_0~T256_1_95 and TS256_1_1~TS256_1_3 are coupled in series with each other and arranged in order. The transistors T256_1_0′~T256_1_95′ and TS256_1_1′~TS256_1_3′ are coupled in series with each other and arranged in order.

In some embodiments, each of control terminals of the transistors TS1_1_1~TS1_1_3 is configured to receive a string select signal SSL1. Each of control terminals of the transistors TS1_1_1′~TS1_1_3′ is configured to receive a string select signal SSL1′. Each of control terminals of the transistors TS2_1_1~TS2_1_3 is configured to receive a string select signal SSL2. Each of control terminals of the transistors TS2_1_1′~TS2_1_3′ is configured to receive a string select signal SSL2′, and so on. Each of control terminals of the transistors TS256_1_1~TS256_1_3 is configured to receive a string select signal SSL256. Each of control terminals of the transistors TS256_1_1′~TS256_1_3′ is configured to receive a string select signal SSL256′.

In some embodiments, before performing the search operation, the memory system 600 trims the transistors TS1_1_1~TS1_1_3, TS1_1_1′~TS1_1_3′, TS256_1_1~TS256_1_3 and TS256_1_1′~TS256_1_3′, such that each of the transistors TS1_1_1~TS1_1_3, TS1_1_1′~TS1_1_3′, TS256_1_1~TS256_1_3 and TS256_1_1′~TS256_1_3′ has the threshold voltage level TVT.

On the other hand, each of the transistors T1_1_0~T256_1_0 and T1_1_0′~T256_1_0′ is configured to receive the word line signal WL0. Each of the transistors T1_1_1~T256_1_1 and T1_1_1′~T256_1_1′ is configured to receive the word line signal WL1, and so on. Each of the transistors T1_1_95~T256_1_95 and T1_1_95′~T256_1_95′ is configured to receive the word line signal WL95. In summary, the memory strings MS1_1~MS256_1 and MS1_1′~MS256_1′ are configured to receive the word line signals WL1~WL95.

In some embodiments, the string select line signals SSL1~SSL256 and SSL1′~SSL256′ are configured to carry query data QDT. Specifically, the query data QDT includes input bits IDB1~IDB256. The string select line signals SSL1 and SSL1′ are configured to carry the input bit IDB1. The string select line signals SSL2 and SSL2′ are configured to carry the input bit IDB2, and so on. The string select line signals SSL256 and SSL256′ are configured to carry the input bit IDB256.

On the other hand, the transistors T1_1_95~T256_1_95 and T1_1_95′~T256_1_95′ are configured to store the stored data SDT1. Specifically, the stored data SDT1 includes stored data bits SDB1_1~SDB1_256. The transistors T1_1_95 and T1_1_95′ are configured to store the stored data bit SDB1_1. The transistors T2_1_95 and T2_1_95′ are configured to store the stored data bit SDB1_2, and so on. The transistors T256_1_95 and T256_1_95′ are configured to store the stored data bit SDB1_256.

Referring to FIG. 4B and FIG. 6C, configurations of the transistors and the string select line signals shown in FIG. 6C are similar with the configurations of the transistors and the string select line signals shown in FIG. 4B. Therefore, for brevity, some descriptions are not repeated. For example, the transistors T1_1_95, T1_1_95′, TS1_1_1~TS1_1_3 and TS1_1_1′~TS1_1_3′ correspond to the transistors T192, T192′, TS1~TS3 and TS1′~TS3′, respectively. The string select line signals SSL1 and SSL1′ correspond to the string select line signals SSL and SSL′, respectively.

In the embodiment shown in FIG. 6C, the word line signal WL95 has the read voltage level VREAD, and each of the word line signals WL0~WL94 has the pass voltage level VPASS. Correspondingly, the memory device 610 can compare the query data QDT and the stored data SDT1.

At this moment, the input bit IDB1 has the logic value 1, such that the string select line signals SSL1 and SSL1′ have the voltage levels VPTO and VL, respectively. Correspondingly, each of transistors TS1_1_1′~TS1_1_3′ is turned off, such that the string current signal IS1_1′ has the current level ISL0.

The stored data bit SDB1_1 has the logic value 1, such that the transistors T1_1_95 and T1_1_95′ have the threshold voltage level HVT and LVT, respectively. Correspondingly, the transistor T1_1_95 is turned off, such that the string current signal IS1_1 has the current level ISL0.

The input bit IDB 256 has the logic value 1, such that the string select line signals SSL256 and SSL256′ have the voltage levels VPTO and VL, respectively. Correspondingly, each of transistors TS256_1_1~TS256_1_3 is turned partially on, and each of transistors TS256_1_1′~TS256_1_3′ is turned off, such that the string current signal IS256_1′ has the current level ISL0.

The stored data bit SDB1_256 has the logic value 0, such that the transistors T256_1_95 and T256_1_95′ have the threshold voltage level LVT and HVT, respectively. Correspondingly, the transistor T256_1_95 is turned on. At this moment, in response to each of transistors TS256_1_1~TS256_1_3 being turned partially on, such that the string current signal IS256_1 has the current level ISLP.

In the embodiment shown in FIG. 6C, the input bits IDB2~IDB255 match the stored data bits SDB1_2~SDB1_255, respectively, such that each of the string current signals IS2_1~IS255_1 and IS2_1′~IS255_1′ has the current level ISL0. Correspondingly, the current level of the bit line signal BL1 is equal to the current level ISLP.

FIG. 6D is a schematic diagram of further details of the memory device 610, illustrated according to some embodiments of present disclosure. As shown in FIG. 6D, the memory string MS1_128K includes transistors T1_128K_0~T1_128K_95 and TS1_128K_1~TS1_128K_3. The memory string MS1_128K′ includes transistors T1_128K_0′~T1_128K_95′ and TS1_128K_1′~TS1_128K_3′. The memory string MS256_128K includes transistors T256_128K_0~T256_128K_95 and TS256_128K_1~TS256_128K_3. The memory string MS256_128K′ includes transistors T256_128K_0′~T256_128K_95′ and TS256_128K_1′~TS256_128K_3′.

The transistors T1_128K_0~T1_128K_95 and TS1_128K_1~TS1_128K_3 are coupled in series with each other and arranged in order. The transistors T1_128K_0′~T1_128K_95′ and TS1_128K_1′~TS1_128K_3′ are coupled in series with each other and arranged in order. The transistors T256_128K_0~T256_128K_95 and TS256_128K_1~TS256_128K_3 are coupled in series with each other and arranged in order. The transistors T256_128K_0′~T256_128K_95′ and TS256_128K_1′~TS256_128K_3′ are coupled in series with each other and arranged in order.

In some embodiments, each of control terminals of the transistors TS1_128K_1~TS1_128K_3 is configured to receive the string select signal SSL1. Each of control terminals of the transistors TS1_128K_1′~TS1_128K_3′ is configured to receive the string select signal SSL1′. Each of control terminals of the transistors TS2_128K_1~TS2_128K_3 is configured to receive the string select signal SSL2. Each of control terminals of the transistors TS2_128K_1′~TS2_128K_3′ is configured to receive the string select signal SSL2′, and so on. Each of control terminals of the transistors TS256_128K_1~TS256_128K_3 is configured to receive a string select signal SSL256. Each of control terminals of the transistors TS256_128K_1′~TS256_128K_3′ is configured to receive a string select signal SSL256′.

In some embodiments, before performing the search operation, the memory system 600 trims the transistors TS1_128K_1~TS1_128K_3, TS1_128K_1′~TS1_128K_3′, TS256_128K_1~TS256_128K_3 and TS256_128K_1′~TS256_128K_3′, such that each of the transistors TS1_128K_1~TS1_128K_3, TS1_128K_1′~TS1_128K_3′, TS256_128K_1~TS256_128K_3 and TS256_128K_1′~TS256_128K_3′ has the threshold voltage level TVT.

On the other hand, each of the transistors T1_128K_0~T256_128K_0 and T1_128K_0′~T256_128K_0′ is configured to receive the word line signal WL0. Each of the transistors T1_128K_1~T256_128K_1 and T1_128K_1′~T256_128K_1′ is configured to receive the word line signal WL1, and so on. Each of the transistors T1_128K_95~T256_128K_95 and T1_128K_95′~T256_128K_95′ is configured to receive the word line signal WL95. In summary, the memory strings MS1_128K~MS256_128K and MS1_128K′~MS256_128K′ are configured to receive the word line signals WL1~WL95.

In some embodiments, the transistors T1_128K_95~T256_128K_95 and T1_128K_95′~T256_128K_95′ are configured to store the stored data SDT128K. Specifically, the stored data SDT128K includes stored data bits SDB128K_1~SDB128K_256. The transistors T1_128K_95 and T1_128K_95′ are configured to store the stored data bit SDB128K_1. The transistors T2_128K_95 and T2_128K_95′ are configured to store the stored data bit SDB128K_2, and so on. The transistors T256_128K_95 and T256_128K_95′ are configured to store the stored data bit SDB128K_256.

In the embodiment shown in FIG. 6D, the word line signal WL95 has the read voltage level VREAD, and each of the word line signals WL0~WL94 has the pass voltage level VPASS. Correspondingly, the memory device 610 can compare the query data QDT and the stored data SDT128K.

At this moment, the input bit IDB1 has the logic value 1, such that the string select line signals SSL1 and SSL1′ have the voltage levels VPTO and VL, respectively. Correspondingly, each of transistors TS1_128K_1′~TS1_128K_3′ is turned off, such that the string current signal IS1_128K′ has the current level ISL0.

The stored data bit SDB128K_1 has the logic value 1, such that the transistors T1_128K_95 and T1_128K_95′ have the threshold voltage level HVT and LVT, respectively. Correspondingly, the transistor T1_128K_95 is turned off, such that the string current signal IS1_128K has the current level ISL0.

The input bit IDB 256 has the logic value 1, such that the string select line signals SSL256 and SSL256′ have the voltage levels VPTO and VL, respectively. Correspondingly, each of transistors TS256_128K_1′~TS256_128K_3′ is turned off, such that the string current signal IS256_128K′ has the current level ISL0.

The stored data bit SDB128K_256 has the logic value 1, such that the transistors T256_128K_95 and T256_128K_95′ have the threshold voltage level HVT and LVT, respectively. Correspondingly, the transistor T256_128K_95 is turned off, such that the string current signal IS256_128K has the current level ISL0.

In the embodiment shown in FIG. 6D, the input bits IDB2~IDB255 match the stored data bits SDB128K_2~SDB128K_255, respectively, such that each of the string current signals IS2_128K~IS255_128K and IS2_128K′~IS255_128K′ has the current level ISL0. Correspondingly, the current level of the bit line signal BL128K is equal to the current level ISL0.

Referring to FIG. 6D and FIG. 6C, in response to the current level ISL0 of the bit line signal BL128K being smaller than the current level ISLP of the bit line signal BL1, the memory system 600 can determine that a similarity between the query QDT and the stored data SDT128K is larger than a similarity between the query QDT and the stored data SDT1.

In some embodiments, the memory cells in present disclosure are referred to as in-memory searching (IMS) cells. In various embodiments, the IMS cells can be implemented by floating gate memory, split-gate memory, silicon-oxide-nitride-oxide-silicon (SONOS) memory, floating dot memory, dynamic random-access memory (DRAM) and/or ferroelectric field-effect transistor (FeFET). The IMS cells can also be implemented by emerging memory, such as ferroelectric field-effect transistor (FeFET) and/or 3D-NOR flash memory.

In various embodiments, the memory devices described in the present disclosure can be implemented by various structures, such as 2D flash structure or 3D flash structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising:
a first memory string configured to receive a first string select line signal to compare a first stored data bit and a first input bit; and
a second memory string configured to receive a second string select line signal to compare the first stored data bit and the first input bit,
wherein the first memory string comprises a first transistor,
when the first input bit has a first logic value, the first string select line signal has a first voltage level,
when the first input bit has a second logic value, the first string select line signal has a second voltage level, and
the first voltage level is within a linear region of the first transistor.

2. The memory device of claim 1, wherein the second memory string comprises a second transistor, and
a control terminal of the first transistor and a control terminal of the second transistor are configured to receive the first string select line signal and the second string select line signal, respectively.

3. The memory device of claim 2, wherein each of the control terminal of the first transistor and the control terminal of the second transistor is configured to receive a predetermined positive bias, to trim each of the first transistor and the second transistor.

4. The memory device of claim 3, wherein after each of the first transistor and the second transistor is trimmed, each of the first transistor and the second transistor has a trim threshold voltage level.

5. The memory device of claim 2, wherein
when the first input bit has the first logic value, the second string select line signal has the second voltage level, and
when the first input bit has the second logic value, the second string select line signal has the first voltage level.

6. The memory device of claim 5, wherein the first memory string and the second memory string comprise a third transistor and a fourth transistor, respectively,
the third transistor and the fourth transistor are configured to store the first stored data bit,
the third transistor and the fourth transistor are coupled in series with the first transistor and the second transistor, respectively, and
each of a control terminal of the third transistor and a control terminal of the fourth transistor is configured to receive a word line signal.

7. The memory device of claim 6, wherein
when the first stored data bit has the first logic value, the third transistor and the fourth transistor has a first threshold voltage level and a second threshold voltage level, respectively, and
when the first stored data bit has the second logic value, the third transistor and the fourth transistor has the second threshold voltage level and the first threshold voltage level, respectively.

8. The memory device of claim 2, wherein the first memory string and the second memory string comprise a third transistor and a fourth transistor, respectively,
the third transistor and the fourth transistor are coupled in series with the first transistor and the second transistor, respectively, and
a control terminal of the third transistor and a control terminal of the fourth transistor are configured to receive the first string select line signal and the second string select line signal.

9. The memory device of claim 8, wherein each of the control terminal of the first transistor, the control terminal of the second transistor, the control terminal of the third transistor and the control terminal of the fourth transistor is configured to receive a predetermined positive bias, to trim each of the first transistor, the second transistor, the third transistor and the fourth transistor.

10. An operating method of a memory device, comprising:
comparing a first stored data bit and a first input bit by a first memory string and a second memory string;
generating a first string current signal by the first memory string;
generating a second string current signal by the second memory string;
comparing the first string current signal and the second string current signal with a predetermined current level; and
when at least one of a current level of the first string current signal and a current level of the second string current signal is larger than the predetermined current level, re-trimming the memory device.

11. The operating method of claim 10, wherein the first memory string and the second memory string comprise a first transistor and a second transistor, respectively,
a control terminal of the first transistor and a control terminal of the second transistor are configured to receive a first string select line signal and a second string select line signal, respectively,
when the first input bit has a first logic value, the first string select line signal has a first voltage level,
when the first input bit has a second logic value, the first string select line signal has a second voltage level, and
the first voltage level is within a linear region of the first transistor.

12. The operating method of claim 11, wherein
when the first input bit has the first logic value, the second string select line signal has the second voltage level, and
when the first input bit has the second logic value, the second string select line signal has the first voltage level.

13. The operating method of claim 12, wherein the first memory string and the second memory string comprise a third transistor and a fourth transistor, respectively,
the third transistor and the fourth transistor are configured to store the first stored data bit,
the third transistor and the fourth transistor are coupled in series with the first transistor and the second transistor, respectively, and
each of a control terminal of the third transistor and a control terminal of the fourth transistor is configured to receive a word line signal.

14. The operating method of claim 13, wherein when the first input bit and the first stored data bit have the first logic value and the second logic value, respectively, the first string current signal and the second string current signal have a first current level and a second current level, respectively.

15. The operating method of claim 14, wherein when the first input bit and the first stored data bit have the second logic value and the first logic value, respectively, the first string current signal and the second string current signal have the second current level and the first current level, respectively.

16. The operating method of claim 15, wherein the predetermined current level is equal to the first current level multiplied by 1.1.

17. The operating method of claim 11, wherein re-trimming the memory device comprises:
applying a predetermined positive bias to each of the first transistor and the second transistor.

18. A memory system, comprising a plurality of memory strings configured to generate a plurality of bit line signals, the plurality of memory strings comprising:
a first memory string and a second memory string configured to receive a first string select line signal and a second string select line signal, respectively, to compare a first stored data bit and a first input bit,
wherein the first memory string comprises a first transistor,
when the first input bit has a first logic value, the first string select line signal has a first voltage level,
when the first input bit has a second logic value, the first string select line signal has a second voltage level, and
the first voltage level is within a linear region of the first transistor.

19. The memory system of claim 18, wherein the plurality of memory strings further comprise:
a third memory string and a fourth memory string configured to receive a third string select line signal and a fourth string select line signal, respectively, to compare a second stored data bit and a second input bit,
wherein the first memory string, the second memory string, the third memory string and the fourth memory string are configured to generate a first string current signal, a second string current signal, a third string current signal and a fourth string current signal, respectively, and configured to sum the first string current signal, the second string current signal, the third string current signal and the fourth string current signal to generate a first bit line signal in the plurality of bit line signals.

20. The memory system of claim 19, wherein the plurality of memory strings further comprise:
a fifth memory string and a sixth memory string configured to receive a fifth string select line signal and a sixth string select line signal, respectively, to compare a third stored data bit and the first input bit,
wherein the fifth memory string and the sixth memory string are configured to generate a fifth string current signal and a sixth string current signal, respectively, and configured to sum the fifth string current signal, the sixth string current signal to generate a second bit line signal in the plurality of bit line signals.
